(19) United States
(12) Patent Application Publication
(10) Pub. No.: US 2004/0142563 A1
(43) Pub. Date: Jul. 22, 2004

(54) Methods and systems for exchanging messages in a controller for a substrate processing system

(75) Inventors: Pierre Fontarensky, Sunnyvale, CA (US); Lakshmanan Karuppiah, San Jose, CA (US)

Correspondence Address: PATENT COUNSEL, APPLIED MATERIALS, INC., Legal Affairs Department, P.O.BOX 450A, Santa Clara, CA, 95052, US

(73) Assignee: Applied Materials, Inc.

(21) Appl. No.: 10/346,398

(22) Filed: Jan. 16, 2003

(51) Int. Cl. H01L 21/00; H01L 21/302; H01L 21/461

(52) U.S. Cl. 438/689

(57) ABSTRACT

In a substrate processing system, a mailbox associated with at least one of a first process and a first thread is locked to prevent access to the mailbox by messages other than a first message from at least one of a second process and a second thread. The first message from the at least one of the second process and the second thread is placed in the mailbox, a message counter in incremented, and the mailbox is unlocked to allow access to the mailbox by messages other than the first message.

### TECHNICAL FIELD

This invention relates to methods and systems for exchanging messages in a controller for a substrate processing system, such as an integrated circuit fabrication system.

### BACKGROUND

An integrated circuit is typically formed on a substrate by the sequential deposition of conductive, semiconductive or insulative layers on a silicon wafer. After each layer is deposited, it is etched to create circuitry features. As a series of layers are sequentially deposited and etched, the outer or uppermost surface of the substrate, i.e., the exposed surface of the substrate, becomes increasingly non-planar. This non-planar surface presents problems in the photolithographic steps of the integrated circuit fabrication process. Therefore, there is a need to periodically planarize the substrate surface.

Chemical mechanical polishing (CMP) is one accepted method of planarization. This planarization method typically requires that the substrate be mounted on a carrier or polishing head of a chemical mechanical polishing system. The exposed surface of the substrate is placed against a rotating polishing pad. The polishing pad can be either a “standard” pad or a fixed-abrasive pad. A standard pad has a durable roughened surface, whereas a fixed-abrasive pad has abrasive particles held in a containment media. The carrier head provides a controllable load, i.e., pressure, on the substrate to push it against the polishing pad. A polishing slurry, including at least one chemically-reactive agent, and abrasive particles if a standard pad is used, is supplied to the surface of the polishing pad.

The chemical mechanical polishing system can be subsystem in an integrated circuit fabrication system, which can also includes other subsystems, such as cleaning stations, drying stations, electrodeposition stations, factory interface modules, and the like. The operations of the integrated circuit fabrication system can be controlled by one or more controllers.

### SUMMARY

In one aspect, the invention is directed to a method for controlling operations in a substrate processing system. In the method, a plurality of processes that control operations of the substrate processing system are run on a computer. A mailbox associated with at least one of a first process and a first thread is locked to prevent access to the mailbox by messages other than a first message from at least one of a second process and a second thread. The first message from the at least one of the second process and the second thread is placed in the mailbox, a message counter in incremented, and the mailbox is unlocked to allow access to the mailbox by messages other than the first message.

Implementations of the invention may include one or more of the following features. The message counter may comprise a counting semaphore. Locking the message queue may comprise changing a value in a binary semaphore. The message queue may be created and associated with the at least one of the first process and the first thread. At least one of the first process and the first thread may act on the first message. The first message may be placed in a memory mapped file.

In another aspect, the invention is directed to a method for controlling operations in an integrated substrate polishing and cleaning system. In the method, a plurality of processes that control operations of the an integrated substrate polishing and cleaning system are run on a computer. A mailbox associated with at least one of a first process and a first thread is locked to prevent access to the mailbox by messages other than a message from at least one of a second process and a second thread. The message to the at least one of the first process and the first thread from at least one of a second process and a second thread is placed in the mailbox. A message counter is incremented, the mailbox is unlocked to allow access to the mailbox by messages other than the first message, the mailbox associated with the at least one of the first process and the first thread is locked,

the message is retrieved from the mailbox, the message counter is decremented, and the mailbox is unlocked.

Implementations of the invention may include on or more of the following features. Retrieving the message from the mailbox may comprises retrieving the message based on a FIFO retrieval process. A signal may be received in the first process or thread from the message counter that a message is available in the mailbox. Whether another message is available may be checked after decrementing the message counter until the message counter indicates that there are no more messages, and reading the next available message may be read after each successful check.

In another aspect, the invention is directed to a system for exchanging messages between at least one of processes and threads in a substrate processing system. The system includes a plurality of processes for processing a substrate, each of the processes comprising at least one thread, and a message system including at least one mailbox, a locking system, and a counter. The at least one mailbox associated with at least one of a first process and a first thread stores messages from at least one of other processes and other threads. The locking system for each mailbox blocks access to the mailbox when a message operation is being performed on the mailbox. The a counter for each mailbox monitors the number of messages in the mailbox. The message operation placing a message in the mailbox or reading a message from the mailbox.

Implementations of the invention may include on or more of the following features. The mailbox may comprise a memory mapping file to store the messages. The memory mapping file may comprise a circular buffer. The locking system may comprise a binary semaphore. The counter may comprise a counting semaphore. The plurality of processes may comprise at least one of a polishing process, a cleaning process, a particle monitoring process, a defect monitoring process, and a substrate transporting process.

In another aspect, the invention is directed to a method of communicating between threads in a multi-thread system. The method comprises transmitting a locking command from a first thread to lock a mailbox from access during a message operation, the mailbox for storing messages directed to an associated thread wherein the associated thread performs at least one action in response to each message in the mailbox, performing a message operation on the mailbox, updating a message counter, and releasing the mailbox.

Implementations of the invention may include on or more of the following features. The message operation may comprise placing a message in the mailbox or retrieving a message from the mailbox. The mailbox may be created. The message operation may be performed by the first thread and may comprise placing a message in the mailbox. A second message operation may be performed by a second thread, and the second message operation may comprises retrieving the message. The message may be acted on. The message queue may be associated with a second thread. Locking the message queue may comprise locking a binary semaphore. Updating the message counter may comprise updating a counting semaphore.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a block diagram illustrating one implementation of a substrate processing system.

FIG. 2 is a block diagram illustrating one implementation of a message exchange system.

FIG. 3 is a block diagram illustrating one implementation of a message queue module of a message exchange system.

FIG. 4 is a block diagram illustrating one implementation of a memory mapped file of a message queue module.

FIG. 5 is a flow diagram illustrating one implementation of a method of transmitting a message from one process to another.

FIG. 6 is a flow diagram illustrating one implementation of a method of receiving, in a process, a message transmitted from another process.

Like reference symbols in the various drawings indicate like elements.

### DETAILED DESCRIPTION

An exchange of messages between threads of processes in a system running parallel processes can be performed using a lockable mailbox system. The mailbox system can include a dynamic link library that is accessible by threads of each of the parallel processes in the system. In one embodiment, the mailbox system can include a mailbox or message queue associated with each of the threads including a memory mapped file and a binary semaphore to lock the message queue when it is being accessed by any thread. The message queue can also include a counting semaphore to keep track of the number of messages in the message queue.

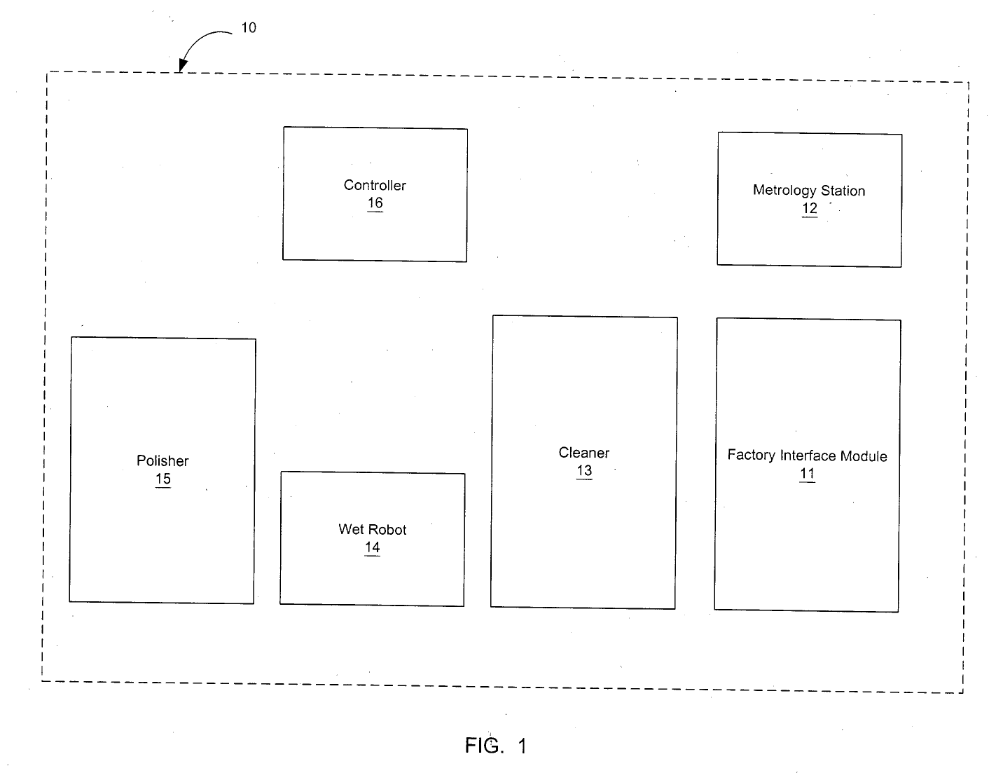

A substrate processing system (i.e., an integrated circuit fabrication system) typically includes multiple independently operating modules. FIG. 1 is a block diagram illustrating one implementation of a substrate processing system. In the implementation shown, the substrate processing system 10 has multiple modules including a factory interface module 11, a metrology station or a particle or defect monitor 12, a cleaner 13, a wet robot 14, and a chemical mechanical polisher 15. In addition, the system 10 has a controller 16 to coordinate operations of the individual modules.

The factory interface module 11 can include a robot that transfers the substrates between the cassettes, the polisher 15 and the cleaner 13. The metrology station 12 can measure the thickness of deposited layers at different points on the substrate, or scan the surface of the substrate for defects such as particles or scratches. The polisher 15 can include polishing stations and a transfer station to receive substrates from the wet robot 14. The cleaner 13 cleans and dries a substrate after it has been polished to remove excess slurry, polishing chemistry and other debris from the polishing operation. The wet robot 14 transports the substrate between the cleaner 13 and the polisher 15, and the robot inside the factory interface module can extract the cleaned and dried substrate from the cleaner.

Substrates are transported to the substrate processing system 10 in cassettes (not shown). In operation, the factory interface module 11 receives an unpolished substrate from a cassette, and places the substrate in a staging section of the cleaner 13. The wet robot 14 extracts the substrate from the staging section and places it in the transfer station of polisher 15. After the polishing operation is completed, the wet robot 14 transports the substrate from the polisher 15 to the cleaner 13. Once the substrate has been cleaned, the factory interface module 11 removes the substrate from the cleaner and inserts it into the monitor 12. After the monitoring operation is completed, the factory interface module 11 extracts the substrate from the monitor 12 and returns it to one of the cassettes.

The operations by the modules in the substrate processing system 10 can be coordinated by the controller 16. The operations of the substrate processing system 10 include the operations performed at factory interface module 11, monitoring system 12, cleaner 13, wet robot 14 and polisher 15. In one implementation, the controller 16 includes one or more programmable digital computers executing control software, such as distributed control software, that causes the modules to perform the appropriate operations to process the substrate.

The control software executed in the controller 16 can include multiple processes for controlling the operations performed in the substrate processing system 10. A process is an instance of an executing computer program. The control software can have one or more processes controlling each module of the substrate processing system 10 or one process can controlling multiple modules of the substrate processing system 10. However, in general, there will be one process for each module. For example, there would typically be one process each for the factory interface module 11, the metrology station 12, the cleaner 13, the wet robot 14 and the polisher 15.

A thread is a part of a process that can be run independently to serve one component or service request. For example, a thread can be created for each platen of the polisher 15 because the software controlling each platen can perform the same operations in parallel and independently.

Coordination of the operations of the substrate processing system 10 can include exchanging messages between processes running in the controller 16, such as between threads of the processes controlling the operations performed at the polisher 15 and the operations performed at the wet robot 14. For example, after polishing is completed on a substrate, the wet robot 14 needs to be signaled to transport the substrate from the polisher 15 to the cleaner 13. The message can be conceived of as information about a state of the subsystem sending the message (or the state of the substrate at subsystem sending the message), or as a request for action by the subsystem receiving the message. For example, once the substrate is properly positioned in a transfer-station, the thread of the process controlling the polisher 15 can sends a message to a thread of the process controlling the wet robot 14 indicating that a substrate is ready to be picked up.

Conventionally, messages are exchanged between processes using Windows® Messaging®. Windows® Messaging® includes translating hardware interrupts into messages. The messages are packaged and transmitted through network communication layers, such as sockets, pipes, mailslots, etc. The messages then have to be extracted from the packaged messages upon receipt. Each subsystem then filters through all available Windows® Messaging® messages (keystrokes, mouse clicks, etc.). The reliability of Windows® Messaging® depends on process activity and user operation.

In contrast, the controller 16 uses a mailbox concept, as described below, to allow message transmission between multiple threads on a given computer. Thus, each process, such as those controlling the operations performed by the factory interface module 11, monitor 12, cleaner 13, wet robot 14 and polisher 15, can include multiple threads that communicate with threads of other processes. The mailbox concept is based on shared memory and multithreading synchronization mechanisms.

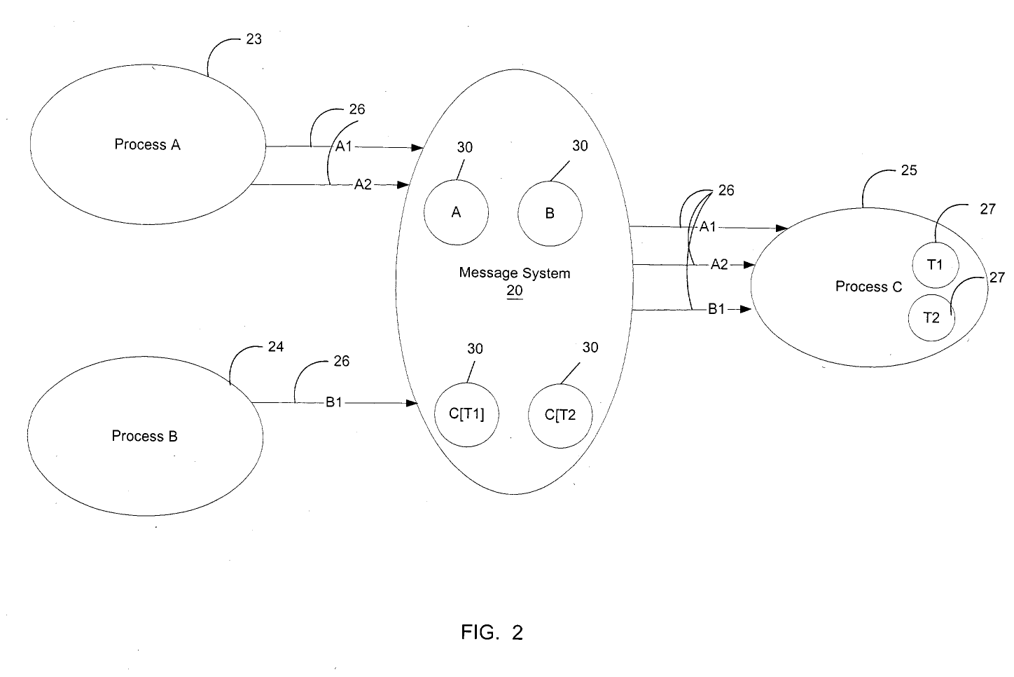

FIG. 2 is a block diagram illustrating one embodiment of a process message exchange Using a mailbox message exchange system. The processes A 23, B 24 and C 25 can include the processes executed in the controller 16 of the substrate processing system 10. Control of the operations of the substrate processing system 10 includes event based programming, where proceeding from one state to another is triggered by messages and events, such as a message from a thread of the process controlling the polisher 15 to a thread of the process controlling the wet robot 14 indicating that a substrate is ready to be picked up.

In the implementation of the message exchange shown, one or more threads of process A 23 transmits two messages 26 to a thread of process C 25, while a thread of process B 24 transmits one message 26 to the thread of process C 25. The threads of processes A 23 and B 24 transmit the messages 26 for the thread of process C 25 through Message System 20.

Message system 20 can include a dynamic link library (“DLL”). A DLL is a module including executable functions and/or data. The DLL can be called by a software application or another DLL to perform a particular function or access data. An application can access the DLL by creating either a dynamic link to the DLL. Several applications can use the DLL at the same time. The DLL of the message system 20 can be attached to any software application through an application program interface (“API”).

In one implementation, each of the main processes can have multiple threads 27, such as T1 and T2, running in parallel. Any thread of any process can create its own mailbox in the DLL of message system 20. The threads 27 communicate directly with each other using the message system 20.

When a message is sent to a specific mailbox, such as the mailbox for a thread T1 of process C 25, the message system 20 can lock the mailbox, add the message to the mailbox memory mapped file, increment a mailbox counter, and then, release the mailbox. The thread T1 can read the message by locking the mailbox, retrieving the message from the mailbox, decrementing the counter, and then, releasing the mailbox. Messages A1, A2, and B1 can each be written into a mailbox belonging to thread T1 without interference from other messages sent. For example, while message A1 is being written into the mailbox belonging to thread T1, messages A2 and B1 will be locked out of the mailbox.

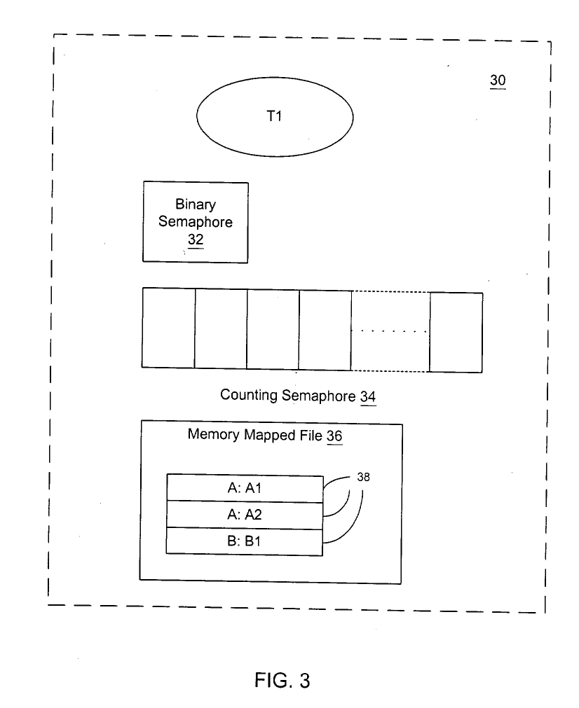

FIG. 3 is a block diagram illustrating one implementation of a message queue module of a message exchange system. In one implementation, the mailbox 30 includes a binary semaphore 32, a counting semaphore 34 and a memory mapped file 36. Each mailbox 30 is associated with a process 23-25, such as process C 25, or a thread 27, such as T1. Conversely, each process 23-25 or thread 27 can be associated with a mailbox 30. Any thread 27 of any process 23-25 can create its own mailbox 30.

The memory mapped file 36 can store one or more incoming messages 26, such as messages A1, A2 and B1, in memory locations 38. The binary semaphore 32 protects the mailbox 30 from being accessed simultaneously by different threads 27 or processes 23-25. The counting semaphore 34 keeps track of the pending messages 26.

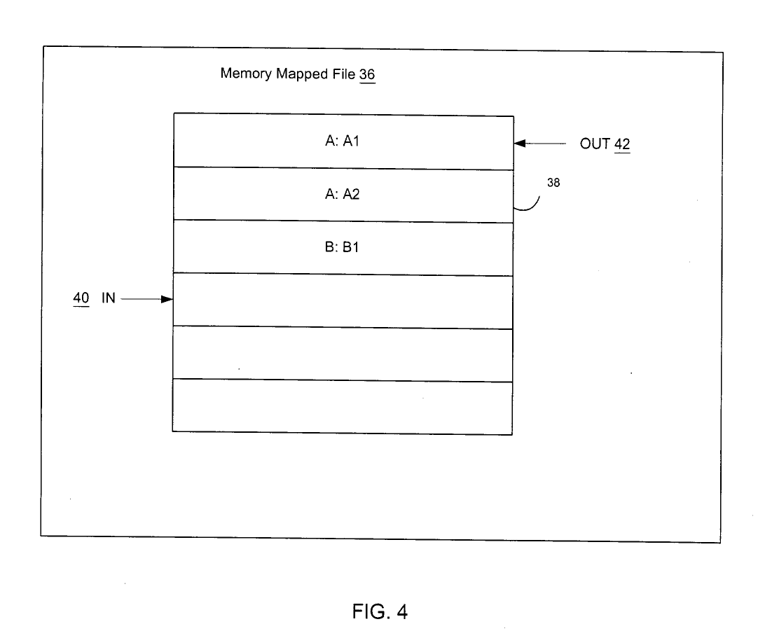

Each memory mapped file, such as memory mapped file C 36, can include a circular buffer having pointers 40, 42 to indicate the memory location 38 at which the next message 26 will come in or be read out, as shown in FIG. 4. The pointer IN 40 indicates in which location the next incoming message 26 will be placed. The pointer OUT 42 indicates from which location 38 the thread 27 or process 23-25 associated with the mailbox 30 will read the next message 26.

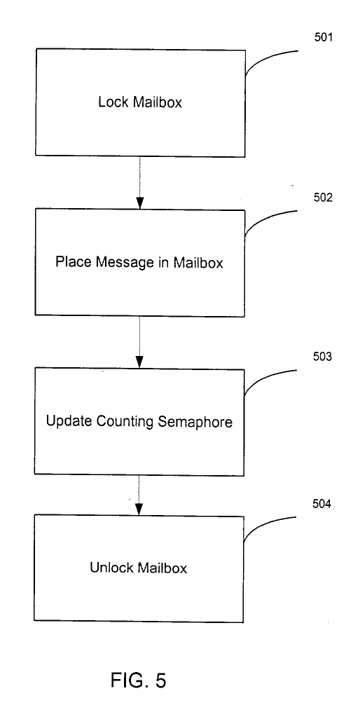

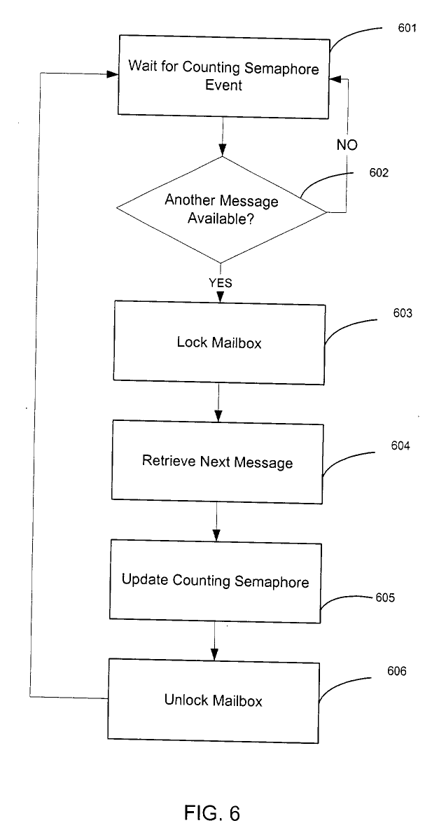

FIGS. 5 and 6 illustrate the processes performed to exchange messages between threads 27 and/or processes 23-25 using the mailbox message exchange system described above with reference to FIGS. 2-4.

FIG. 5 illustrates one implementation of a method of transmitting a message 26 from one process 23-25 or thread 27 to another. At step 501, a process 23-25 or thread 27 sending a message locks mailbox 30 of the process 23-25 or thread 27 to which it is sending the message through message system 20. The message system 20 can lock mailbox 30 by changing the value in binary semaphore 32. If other processes 23-25 or threads 27 send a message, the processes 23-25 or threads 27 will see that the value in binary semaphore 32 indicates that the mailbox is unavailable. When the mailbox 30 is available again, Windows® will transmit a signal to processes 23-25 or threads 27 that are locked out of the mailbox and the processes 23-25 or threads 27 can resend the message.

At step 502, the message 26 is placed in the mailbox 30. Placing the message 26 in the mailbox 30 includes placing the message 26 in the memory mapped file 36 of the mailbox 30. At step 503, the counting semaphore 34 is updated. Updating the counting semaphore 34 when 30 placing a message 26 in a mailbox 30 includes incrementing the counting semaphore by 1. At step 504, the mailbox 30 is unlocked. Unlocking the mailbox can include changing the value of the binary semaphore 32 back to its original value to indicate that the mailbox is no longer busy.

When the process 23-25 or thread 27 associated with the mailbox 30 reads the message(s) 26 in the mailbox, the associated process 23-25 or thread 27 follows a procedure such as the process described with reference to FIG. 6. FIG. 6 is a flow diagram illustrating one implementation of a method of receiving a message transmitted from another process 23-25 or thread 27. In one implementation, the process 23-25 or thread 27 starts the read procedure described below in response to a signal from the counting semaphore that a message is available.

At step 601, the process 23-25 or thread 27 waits for a counting semaphore event to occur. When a counting semaphore event occurs, the process 23-25 or thread 27 checks if there is a message in the mailbox 30 at step 602. The process 23-25 or thread 27 can determine if a message is in the mailbox by examining the counting semaphore 34. For example, if IN 40 and OUT 42 point to the same memory location, no messages are available in the mailbox. If there is a message in the mailbox, the process 23-25 or thread 27 proceeds to step 603. If there are no messages available in the mailbox, the process 23-25 or thread 27 returns to step 602 to wait for another counting semaphore event.

At step 603, the process 23-25 or thread 27 locks mailbox 30. The locking procedure is the same as described with reference to step 501. At step 604, the process 23-25 or thread 27 reads the next available message (i.e., the message in the location to which OUT 42 is pointing). The counting semaphore 34 is then updated at step 605. Updating the counting semaphore 34 can include decrementing the counting semaphore 34 by 1.

The process 23-25 or thread 27 unlocks the mailbox at step 606. Then, the process 23-25 or thread 27 returns to step 601 to wait for another counting semaphore event.

A number of embodiments of the invention have been described. Nevertheless, it will be understood that various modifications may be made without departing from the spirit and scope of the invention. Accordingly, other embodiments are within the scope of the following claims.

What is claimed is:

1. A method for controlling operations in a substrate processing system, comprising:
running on a computer a plurality of processes that control operations of the substrate processing system;
locking a mailbox associated with at least one of a first process and a first thread to prevent access to the mailbox by messages other than a first message from at least one of a second process and a second thread;
placing the first message from the at least one of the second process and the second thread in the mailbox;
incrementing a message counter; and
unlocking the mailbox to allow access to the mailbox by messages other than the first message.

2. The method of claim 1, wherein the message counter comprises a counting semaphore.

3. The method of claim 1, wherein locking the message queue comprises changing a value in a binary semaphore.

4. The method of claim 1, further comprising creating the message queue and associating it with the at least one of the first process and the first thread.

5. The method of claim 1, further comprising at least one of the first process and the first thread acting on the first message.

6. The method of claim 1, wherein placing the first message in the mailbox comprises placing the first message in a memory mapped file.

7. A method for controlling operations in an integrated substrate polishing and cleaning system, comprising:
running on a computer a plurality of processes that control operations of the an integrated substrate polishing and cleaning system;
locking a mailbox associated with at least one of a first process and a first thread to prevent access to the mailbox by messages other than a message from at least one of a second process and a second thread;
placing the message to the at least one of the first process and the first thread from at least one of a second process and a second thread in the mailbox;
incrementing a message counter;
unlocking the mailbox to allow access to the mailbox by messages other than the first message;
locking the mailbox associated with the at least one of the first process and the first thread;
retrieving the message from the mailbox;
decrementing the message counter; and
unlocking the mailbox.

8. The method of claim 7, wherein retrieving the message from the mailbox comprises retrieving the message based on a FIFO retrieval process.

9. The method of claim 7, further comprising receiving in the first process or thread a signal from the message counter that a message is available in the mailbox.

10. The method of claim 7, further comprising checking if another message is available after decrementing the message counter until the message counter indicates that there are no more messages, and reading the next available message after each successful check.

11. A system for exchanging messages between at least one of processes and threads in a substrate processing system, comprising:
a plurality of processes for processing a substrate, each of the processes comprising at least one thread; and
a message system including
at least one mailbox associated with at least one of a first process and a first thread to store messages from at least one of other processes and other threads,
a locking system for each mailbox to block access to the mailbox when a message operation is being performed on the mailbox, and
a counter for each mailbox to monitor the number of messages in the mailbox,
wherein the message operation comprises one of placing a message in the mailbox and reading a message from the mailbox.

12. The system of claim 11, wherein the mailbox comprises a memory mapping file to store the messages.

13. The system of claim 11, wherein the memory mapping file comprises a circular buffer.

14. The system of claim 11, wherein the locking system comprises a binary semaphore.

15. The system of claim 11, wherein the counter comprises a counting semaphore.

16. The system of claim 11, wherein the plurality of processes comprises at least one of a polishing process, a cleaning process, a particle monitoring process, a defect monitoring process, and a substrate transporting process.

17. A method of communicating between threads in a multi-thread system, the method comprising:
transmitting a locking command from a first thread to lock a mailbox from access during a message operation, the mailbox for storing messages directed to an associated thread wherein the associated thread performs at least one action in response to each message in the mailbox;
performing a message operation on the mailbox;
updating a message counter; and
releasing the mailbox.

18. The method of claim 17, wherein the message operation comprises one of placing a message in the mailbox and retrieving a message from the mailbox.

19. The method of claim 17, further comprising creating the mailbox.

20. The method of claim 17, wherein the message operation is performed by the first thread and comprises placing a message in the mailbox, the method further comprising performing a second message operation by a second thread, wherein the second message operation comprises retrieving the message.

21. The method of claim 17, further comprising acting on the message.

22. The method of claim 17, wherein the message queue is associated with a second thread.

23. The method of claim 17, wherein locking the message queue comprises locking a binary semaphore.

24. The method of claim 17, wherein updating the message counter comprises updating a counting semaphore.
